(19) United States
(12) Patent Application Publication
(10) Pub. No.: US 2026/0090020 A1
(43) Pub. Date: Mar. 26, 2026

(54) THIN-FILM TRANSISTOR (TFT) AND CAPACITOR STRUCTURES WITH HIGH DIELECTRIC CONSTANT LAYERS FOR ORGANIC LIGHT-EMITTING DIODE (OLED) DISPLAY BACKPLANE PANELS

(71) Applicant: Applied Materials, Inc., Santa Clara, CA (US)

(72) Inventors: Jung Bae KIM, San Jose, CA (US); Dejiu FAN, Santa Clara, CA (US); Yang Ho BAE, Santa Clara, CA (US); Rodney Shunleong LIM, Daly City, CA (US); Ming Chin HUNG, San Jose, CA (US); Cheng-Hsing CHEN, Hsinchu (TW); Kwang Soo HUH, Palo Alto, CA (US); Lai ZHAO, Campbell, CA (US); Soo Young CHOI, Fremont, CA (US)

(21) Appl. No.: 19/277,902

(22) Filed: Jul. 23, 2025

Related U.S. Application Data
(60) Provisional application No. 63/697,668, filed on Sep. 23, 2024.

(51) Int. Cl. H10D 30/67; H10D 86/40; H10D 86/60

(52) U.S. Cl. CPC H10D 30/6734; H10D 30/6745; H10D 86/481; H10D 86/60

(57) ABSTRACT

Embodiments disclosed herein generally relate to thin-film transistor (TFT) and capacitor structures. The structures include one or more layers having a dielectric constant greater than five. The layer(s) having the dielectric constant greater than five may be implemented in a second buffer layer, a first bottom gate insulator (GI) layer, a first top GI layer, a second top GI layer, a first low temperature polycrystalline silicon (LTPS) interlayer dielectric (ILD) layer, and/or a first ILD layer. The first top GI layer may also have a dielectric constant less than five. Implementing the layer(s) with different dielectric constants results in various functional improvements of TFT and capacitor structures.

### CROSS-REFERENCE TO RELATED APPLICATION

This application claims the benefit of U.S. Provisional Patent Application No. 63/697,668, filed Sep. 23, 2024, which is incorporated by reference herein in its entirety.

### BACKGROUND

### Field

Embodiments of the present disclosure generally relate to semiconductor device structures for display devices. More specifically, embodiments described herein relate to driving thin-film transistor (TFT) structures with one or more layers having a high dielectric constant (e.g., greater than five).

### Description of the Related Art

Thin-film transistors (TFTs) are metal oxide layered semiconductor devices used in integrated circuits and in displays to control pixel operation. TFTs have gained significant interest in display applications due to their high resolution, low power consumption, and high speed operation for liquid crystal display (LCD) and organic light-emitting diode (OLED) displays. Current materials used in the layers making up TFTs often have low current for switching TFT structures, sub-threshold slope values for driving TFT structures, and low capacitance values for capacitor structures in pixel and gate driver on array (GOA) circuits due to the composition and/or dielectric constant of the layer(s) included in the TFT and capacitor structures.

Accordingly, what is needed in the art are improved TFT and capacitor structures. In particular, there is a need for improved layer compositions for high current switching TFT structures, large sub-threshold slope values for driving TFT structures, and large capacitance values for capacitor structures.

### SUMMARY

Embodiments disclosed herein generally relate to devices including driving thin-film transistor (TFT) structures, switching TFT structures, and capacitor structures. The driving TFT structures, switching TFT structures, and capacitor structures include one or more layers having a high dielectric constant (e.g., greater than five).

One exemplary TFT structure includes a first buffer layer, a first bottom gate disposed on the first buffer layer, a second buffer layer disposed on the first bottom gate, a second bottom gate disposed on the second buffer layer, a first bottom gate insulator (GI) layer disposed on the second bottom gate, a metal oxide layer disposed on the first bottom GI layer, a first top GI layer disposed on the metal oxide layer, a first top gate disposed on the first top GI layer, and a first interlayer dielectric (ILD) layer disposed on the first top gate and the metal oxide layer, wherein the second buffer layer and the first bottom GI layer have a dielectric constant greater than five.

Another exemplary TFT structure includes a first low temperature polycrystalline silicon (LTPS) buffer layer, a first LTPS top GI layer disposed on the first LTPS buffer layer, a first LTPS top gate disposed on the first LTPS top GI layer, a first LTPS ILD layer disposed on the first LTPS top gate, a first bottom gate disposed on the first LTPS ILD layer, a first bottom GI layer disposed on the first bottom gate, a metal oxide layer disposed on the first bottom GI layer, a first top GI layer disposed on the metal oxide layer, a first top gate disposed on the first top GI layer, and a first ILD layer disposed on the first top gate and the metal oxide layer, wherein the first LTPS ILD layer and the first bottom GI layer have a dielectric constant that is greater than five.

Yet another exemplary TFT structure includes a first buffer layer, a first bottom gate disposed on the first buffer layer, a first bottom GI layer disposed on the first bottom gate, a metal oxide layer disposed on the first bottom GI layer, a first top GI layer disposed on the metal oxide layer, and a first ILD layer disposed on the metal oxide layer, wherein the first bottom GI layer and the first ILD layer have a dielectric constant greater than five.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only typical embodiments of this disclosure and are therefore not to be considered limiting of its scope, for the disclosure may admit to other equally effective embodiments.

FIG. 1A is a schematic cross-sectional view of an exemplary device including a second buffer layer and a first bottom gate insulator (GI) layer having a dielectric constant greater than five, according to embodiments.

FIG. 1B is a schematic cross-sectional view of exemplary sublayer sets of the bottom GI layer and/or a buffer layer of FIG. 1A, according to embodiments.

FIG. 1C is a schematic cross-sectional view of exemplary sublayer sets of a top GI layer of FIG. 1A, according to embodiments.

FIGS. 2-3 are schematic cross-sectional views of other exemplary devices including a first bottom GI layer and a first interlayer dielectric (ILD) layer having a dielectric constant greater than five, according to embodiments.

FIG. 4 is a schematic cross-sectional view of another exemplary device including a second buffer layer, a first bottom GI layer, and a second top GI layer having a dielectric constant greater than five, according to embodiments.

FIG. 5 is a schematic cross-sectional view of another exemplary device including a second buffer layer, a first bottom GI layer, and a first ILD layer having a dielectric constant greater than five, according to embodiments.

FIGS. 6-8 are schematic cross-sectional views of other exemplary devices including a first low temperature polycrystalline silicon (LTPS) ILD layer and a first bottom GI layer having a dielectric constant greater than five, according to embodiments.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

Embodiments disclosed herein generally relate to semiconductor device structures, such as thin-film transistor (TFT) structures, which include one or more layers formed by atomic layer deposition (ALD). In certain examples, the layer(s) formed by ALD may be included in, or formed adjacent to, a first gate insulator (GI) layer, a second GI layer, and/or an interlayer dielectric (ILD) layer. TFT structures including a layer formed by ALD exhibit various improvements in performance over conventional TFTs without such layers.

Note that, although the following embodiments are described with reference to TFT structures, in various embodiments, the techniques and arrangements described herein may be implemented in other semiconductor devices and structures.

Current organic light-emitting diode (OLED) displays suffer from low grey image Mura (e.g., irregularities or non-uniformities in brightness, color, or luminance on the displays), which is caused by low current switching TFT structures, small sub-threshold slope values for driving TFT structures, and low capacitance value capacitor structures in pixel circuits and gate driver on array (GOA) circuits. Such TFT and capacitor structures are further hindered by high power consumption.

The devices described herein provide driving TFT structures with large sub-threshold values, switching TFT structures that support high currents, and capacitor structures with large capacitance values. In various embodiments, the large sub-threshold values, high currents, and large capacitance values are achieved by including one or more layers having a dielectric constant that is greater than five (referred to herein as a “high-k layer” or a “high-k sublayer”). The high-k layer(s) refer to layer(s) comprised of one or more of silicon oxide (SiOx), silicon nitride (SiNx), silicon oxynitride (SiON), aluminum oxide (AlOx), hafnium oxide (HfOx), zirconium oxide (ZrOx), and titanium oxide (TiOx). By incorporating one or more high-k layers, or layers having a dielectric constant greater than five, the TFT and capacitor structures improve high resolution OLED displays by increasing image quality and solving low grey image Mura issues. For example, OLED displays with TFT and capacitor structures having one or more high-k layers may experience less cloudy patches, streaks, or other visual anomalies on the displays.

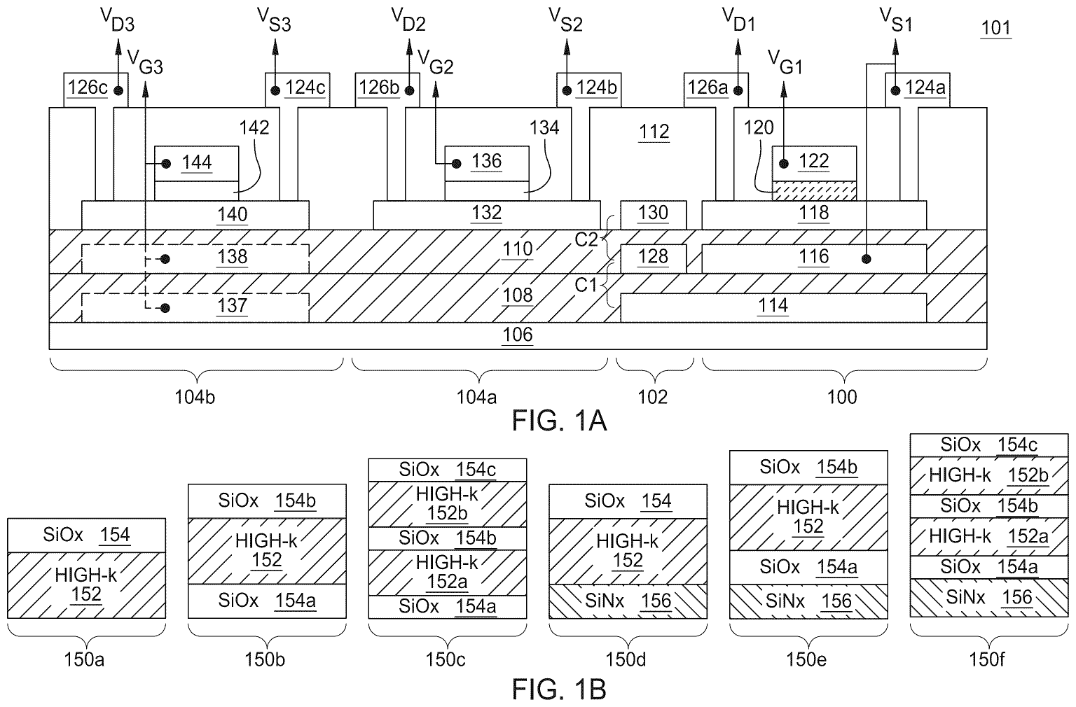

FIG. 1A is a schematic cross-sectional view of an exemplary device 101 including a second buffer layer 108 and a first bottom gate insulator (GI) layer 110 having a dielectric constant greater than five, according to embodiments. The exemplary device 101 includes a driving TFT structure 100, a capacitor structure 102, and a switching TFT structure (sometimes referred to herein as an “additional TFT structure”), which may optionally be a first switching TFT structure 104a or a second switching TFT structure 104b.

The driving TFT structure 100 includes a first buffer layer 106. The first buffer layer 106 is formed by physical vapor deposition or other suitable deposition methods, such as atomic layer deposition (ALD), chemical vapor deposition (CVD), or plasma enhanced chemical vapor deposition (PECVD). The first buffer layer 106 is composed of a material comprising a p-type silicon (e.g., boron-doped silicon), metal nitride (e.g., aluminum nitride or tungsten nitride), metal oxide (e.g., vanadium oxide), or combination(s) thereof. In some embodiments, which can be combined with other embodiments described herein, the first buffer layer 106 includes at least one of SiOx, SiNx, and combinations thereof. Unless otherwise specified, any of the layers of the driving TFT structure 100 and/or the switching TFT structures 104a, 104b can be deposited using any suitable deposition method known in the industry and/or described herein.

A first bottom gate 114 of the driving TFT structure 100 is disposed on the first buffer layer 106. The first bottom gate 114 is formed of a material that includes at least one of molybdenum (Mo), chromium (Cr), copper (Cu), titanium (Ti), tantalum (Ta), tungsten (W), an alloy metal such as MoW, a combination of conductive materials such as MoW, TiCu, MoCu, MoCuMo, TiCuTi, MoWCu, MoWCuMoW, an electrically conductive material such as a conductive metal oxide like indium tin oxide (InSnO) (ITO) or indium zinc oxide (InZnO) (IZO), combinations thereof, or the like. In various embodiments, the first bottom gate 114 is deposited in a single operation, but multiple deposition operations are also contemplated. For example, material of the first bottom gate 114 may be deposited in a first suboperation to form a metal layer, and one or more residual portions of the metal layer may be thereafter etched in a second suboperation to make the first bottom gate 114. The first bottom gate 114 is configured to be connected to a gate line signal as a power source (not shown) to provide a voltage across layers of the driving TFT structure 100.

A second buffer layer 108 is disposed over the first bottom gate 114 and portions of the first buffer layer 106. The second buffer layer 108 has a dielectric constant greater than five. Accordingly, the second buffer layer 108 is comprised of one or more of SiNx, SiOx, SION, AlOx, HfOx, ZrOx, and TiOx resulting in a dielectric constant of greater than five. The second buffer layer 108 has a thickness that is less than 300 nanometers (nm). The second buffer layer 108 may be formed using techniques similar to those used to form the first buffer layer 106. The composition of the second buffer layer 108 is described in further detail with reference to FIG. 1B.

A second bottom gate 116 of the driving TFT structure 100 is disposed on the second buffer layer 108. The second bottom gate 116 is formed using similar materials and techniques to those used to form the first bottom gate 114.

A first bottom gate insulator (GI) layer 110 is disposed over the second bottom gate 116 and portions of the second buffer layer 108. The first bottom GI layer 110 has a dielectric constant greater than five and can include a single layer or a plurality of sublayers, which can each be deposited by CVD or PECVD. Accordingly, in various embodiments, the first bottom GI layer 110 is comprised of one or more of SiNx, SiOx, SiON, AlOx, HfOx, ZrOx, and TiOx resulting in a dielectric constant of greater than five. The first bottom GI layer 110 has a thickness that is less than 500 nanometers (nm). The composition of the first bottom GI layer 110 is described in further detail with reference to FIG. 1B.

A metal oxide layer 118 is disposed on the first bottom GI layer 110. The metal oxide layer 118 can be formed by physical vapor deposition (PVD), PECVD, CVD, or ALD. In particular, the metal oxide layer 118 is deposited by a high density plasma chemical vapor deposition (HDPCVD) process. It is contemplated that the metal oxide layer 118 is formed of a material that includes oxygen (O) and at least one of indium (In), zinc (Zn), gallium (Ga), tin (Sn), aluminum (AI), and hafnium (Hf). Examples of materials for the metal oxide layer 118 include, but are not limited to, In—Ga—Zn—O, In—Zn—O, In—Ga—Sn—O, In—Zn—Sn—O In—Ga—Zn—Sn—O, In—Sn—O, Hf—In—Zn—O, Ga—Zn—O, In—O, Al-Sn—Zn—O, Zn—O, Zn—Sn—O, Al—Zn—O, Al—Zn—Sn—O, Hf—Zn—O, Sn—O, and Al-Sn—Zn—In—O. Further, the material of the metal oxide layer 118 can include an indium oxide (InxOy) contained semiconductor layer. The metal oxide layer 118 may also be doped with n-type or p-type dopants, such as boron (B) or nitrogen (N), or high oxygen affinity metal such W, Ta, Ti, iron (Fe), nickel (Ni), cobalt (Co), or neodymium (Nd).

Further, the metal oxide layer 118 is patterned using any suitable methods of patterning, such as by a wet etch process. For example, the patterning may include forming either a photolithographic mask or a hard mask (not shown) over the metal oxide layer 118 exposing the metal oxide layer 118 to an etchant which is referred to herein as “etching.” Depending on the material used in the metal oxide layer 118, the metal oxide layer 118 can be patterned by exposing portions thereof not covered by a mask to a wet etchant, or by exposing portions of the metal oxide layer 118 not covered by the mask to an etching plasma. Further, the metal oxide layer 118 can be patterned by etching portions of the metal oxide layer 118 not covered by the mask to an etching plasma, such as a plasma including sulfur hexafluoride gas, oxygen gas, chlorine gas, or combination(s) thereof. The etching plasma and the etching process described can be used in any of the patterning and etching of any layer described herein.

A first top GI layer 120 is disposed on the metal oxide layer 118. The first top GI layer 120 may have dielectric constant greater than five or less than five. When the dielectric constant of the first top GI layer 120 is greater than five, the first top GI layer 120 is comprised of one or more of SiOx, AlOx, HfOx, ZrOx, and TiOx. The first top GI layer 120 has a thickness that is less than 300 nm. A first top gate 122 is formed over the first top GI layer 120. The first top gate 122 of the first driving TFT structure 100 is associated with a gate voltage V_{G1}. In various embodiments, the first top gate 122 is formed using similar materials and techniques to those used to form the first bottom gate 114 and the second bottom gate 116.

A first interlayer dielectric (ILD) layer 112 is formed over the first top gate 122, portions of the metal oxide layer 118, and portions of the first bottom GI layer 110. The first ILD layer 112 includes a single layer formed by CVD or PECVD. Alternatively, the first ILD layer 112 includes a plurality of sublayers formed by CVD or PECVD. The first ILD layer 112 has a thickness that is approximately 600 nm. The first ILD layer 112 may be formed of one or more insulating materials such as single SiOx, SiNx, multi-layer silicon nitride/silicon oxide (SiNx/SiOx), silicon oxynitride (SiON), other insulating materials, combinations thereof, and the like. It is contemplated that the first ILD layer 112 is further planarized by chemical mechanical polishing (CMP). The first ILD layer 112 also undergoes a via carbon nanotube (CNT) etch process. For example, the first ILD layer 112 is etched to form bores in the driving TFT structure 100 for subsequent source and drain electrode metallization. The etch process may be a dry etch process or a plasma-based etch process.

A first source electrode 124a and a first drain electrode 126a are then formed in the driving TFT structure 100. Portions of the first ILD layer 112 that expose the metal oxide layer 118 are filled with a conducting material to form the first source electrode 124a and the first drain electrode 126a. The conducting material may include at least one of Mo, Cr, Cu, Ti, Ta, W, an alloy metal such as MoW, a combination of conductive materials such as MoW, TiCu, MoCu, MoCuMo, TiCuTi, MoWCu, and MoWCuMoW, a metal oxide such as ITO or IZO, any combinations thereof, or the like. Thus, the first source electrode 124a and the first drain electrode 126a are in contact with the metal oxide layer 118. The first source electrode 124a and the second bottom gate 116 are associated with a source voltage V_{S1}. The first drain electrode 126a is associated with a drain voltage V_{D1}.

The capacitor structure 102 is coupled to the driving TFT structure 100 and includes a first capacitor C1 and/or a second capacitor C2. The first capacitor C1 includes a portion of the first bottom gate 114, the second buffer layer 108, and a portion of a second bottom gate 128. That is, the first capacitor C1 shares a portion of the first bottom gate 114 with the driving TFT structure 100. The second capacitor C2 includes an additional portion of the second bottom gate 128, a portion of the first bottom GI layer 110 disposed over the additional portion of the second bottom gate 128, and a metal oxide layer 130 disposed on the first bottom GI layer 110. Thus, the second capacitor C2 is formed above the first capacitor C1.

The device 101 further includes a switching TFT structure such as, for example, the first switching TFT structure 104a or the second switching TFT structure 104b. When the device 101 includes the first switching TFT structure 104a, the first switching TFT structure 104a is coupled to the capacitor structure 102 and the driving TFT structure 100. When the device 101 includes the second switching TFT structure 104b, the second switching TFT structure 104b is coupled to the capacitor structure 102 and the driving TFT structure 100.

The first switching TFT structure 104a includes a metal oxide layer 132 disposed on the first bottom GI layer 110, a first top GI layer 134 disposed on a portion of the metal oxide layer 132, a first top gate 136 disposed on the first top GI layer 134, and the first ILD layer 112 disposed on the first top gate 136 and portions of the metal oxide layer 132 and the first bottom GI layer 110. The first top gate 136 of the first switching TFT structure 104a is associated with a gate voltage V_{G2}. The first switching TFT structure 104a further includes a second source electrode 124b and a second drain electrode 126b formed using similar techniques to those used to form the first source electrode 124a and the first drain electrode 126a. The second source electrode 124b and the second drain electrode 126b are associated with a source voltage V_{S2} and a drain voltage V_{D2}, respectively.

The second switching TFT structure 104b includes a first bottom gate 137 disposed on the first buffer layer 106, or a second bottom gate 138 disposed on the second buffer layer 108. The first bottom gate 137 and the second bottom gate 138 may be collectively referred to herein as the bottom gate 137 or 138. The second switching TFT structure 104b further includes a metal oxide layer 140 disposed on the first bottom GI layer 110, a first top GI layer 142 disposed on a portion of the metal oxide layer 140, a first top gate 144 disposed on the first top GI layer 142, and the first ILD layer 112 disposed on the first top gate 144 and portions of the metal oxide layer 140 and the first bottom GI layer 110. The first top gate 144 and the bottom gate 137 or 138 of the second switching TFT structure 104b are associated with a gate voltage V_{G3}. The second switching TFT structure 104b further includes a third source electrode 124c and a third drain electrode 126c formed using similar techniques to those used to form the first source electrode 124a and the first drain electrode 126a. The third source electrode 124c and the third drain electrode 126c are associated with a source voltage V_{S3} and a drain voltage V_{D3}, respectively.

FIG. 1B is a schematic cross-sectional view of exemplary sublayer sets 150a-f of the first bottom GI layer 110 and/or one or more buffer layers (e.g., the first buffer layer 106 and/or the second buffer layer 108) of FIG. 1A, according to embodiments. In other words, the first bottom GI layer 110 and/or the buffer layer may be comprised of any one of the exemplary sublayer sets 150a-f. Each of the sublayer sets 150a-f includes at least one “high-k” sublayer (e.g., high-k sublayer 152, 152a, and/or 152b), which results in the sublayer sets 150a-f having a dielectric constant greater than five. The high-k sublayers 152, 152a, 152b are comprised of one or more of SiNx, SiOx, SiON, AlOx, HfOx, ZrOx, and TiOx, resulting in a dielectric constant of greater than five.

A first sublayer set 150a comprises a high-k sublayer 152 and a SiOx sublayer 154 disposed on the high-k sublayer 152. A second sublayer set 150b comprises a first SiOx sublayer 154a, a high-k sublayer 152 disposed on the first SiOx sublayer 154a, and a second SiOx sublayer 154b disposed on the high-k sublayer 152. A third sublayer set 150c comprises a first SiOx sublayer 154a, a first high-k sublayer 152a disposed on the first SiOx sublayer 154a, a second SiOx sublayer 154b disposed on the first high-k sublayer 152a, a second high-k sublayer 152b disposed on the second SiOx sublayer 154b, and a third SiOx sublayer 154c disposed on the second high-k sublayer 152b. A fourth sublayer set 150d comprises a SiNx sublayer 156, a high-k sublayer 152 disposed on the SiNx sublayer 156, and a SiOx sublayer 154 disposed on the high-k sublayer 152. A fifth sublayer set 150e comprises a SiNx sublayer 156, a first SiOx sublayer 154a disposed on the SiNx sublayer 156, a high-k sublayer 152 disposed on the first SiOx sublayer 154a, and a second SiOx sublayer 154b disposed on the high-k sublayer 152. A sixth sublayer set 150f comprises a SiNx sublayer 156, a first SiOx sublayer 154a disposed on the SiNx sublayer 156, a first high-k sublayer 152a disposed on the first SiOx sublayer 154a, a second SiOx sublayer 154b disposed on the first high-k sublayer 152a, a second high-k sublayer 152b disposed on the second SiOx sublayer 154b, and a third SiOx sublayer 154c disposed on the second high-k sublayer 152b.

Typically, the first bottom GI layer 110 and/or the buffer layer(s) are comprised of one SiOx sublayer, or a SiNx sublayer and a SiOx sublayer disposed on the SiNx sublayer. However, by forming the first bottom GI layer 110 and/or the buffer layer(s) with one of the sublayer sets 150a-f, the first bottom GI layer 110 and/or the buffer layer(s) have a dielectric constant greater than five.

FIG. 1C is a schematic cross-sectional view of exemplary sublayer sets 160a-c of the top GI layer 120 of FIG. 1A, according to embodiments. In other words, the top GI layer 120 may be comprised of any one of the exemplary sublayer sets 160a-c. Each of the sublayer sets 160a-c includes at least one “high-k” sublayer (e.g., high-k sublayer 164, 164a, and/or 164b), which results in the sublayer sets 160a-c having a dielectric constant greater than five. The high-k sublayers 164, 164a, 164b are comprised of one or more of SiNx, SiOx, SiON, AlOx, HfOx, ZrOx, and TiOx, resulting in a dielectric constant of greater than five.

A first sublayer set 160a comprises a SiOx sublayer 162 and a high-k sublayer 164 disposed on the SiOx sublayer 162. A second sublayer set 160b comprises a first SiOx sublayer 162a, a high-k sublayer 164 disposed on the first SiOx sublayer 162a, and a second SiOx sublayer 162b disposed on the high-k sublayer 164. A third sublayer set 160c comprises a first SiOx sublayer 162a, a first high-k sublayer 164a disposed on the first SiOx sublayer 162a, a second SiOx sublayer 162b disposed on the first high-k sublayer 164a, a second high-k sublayer 164b disposed on the second SiOx sublayer 162b, and a third SiOx sublayer 162c disposed on the second high-k sublayer 164b. In each of the sublayer sets 160a-c, a thickness of the high-k sublayers 164, 164a, 164b is greater than a thickness of the SiOx sublayers 162, 162a, 162b, 162c.

Typically, the top GI layer 120 is comprised of one SiOx sublayer. However, by forming the top GI layer 120 with one of the sublayer sets 160a-c, the top GI layer 120 has a dielectric constant greater than five.

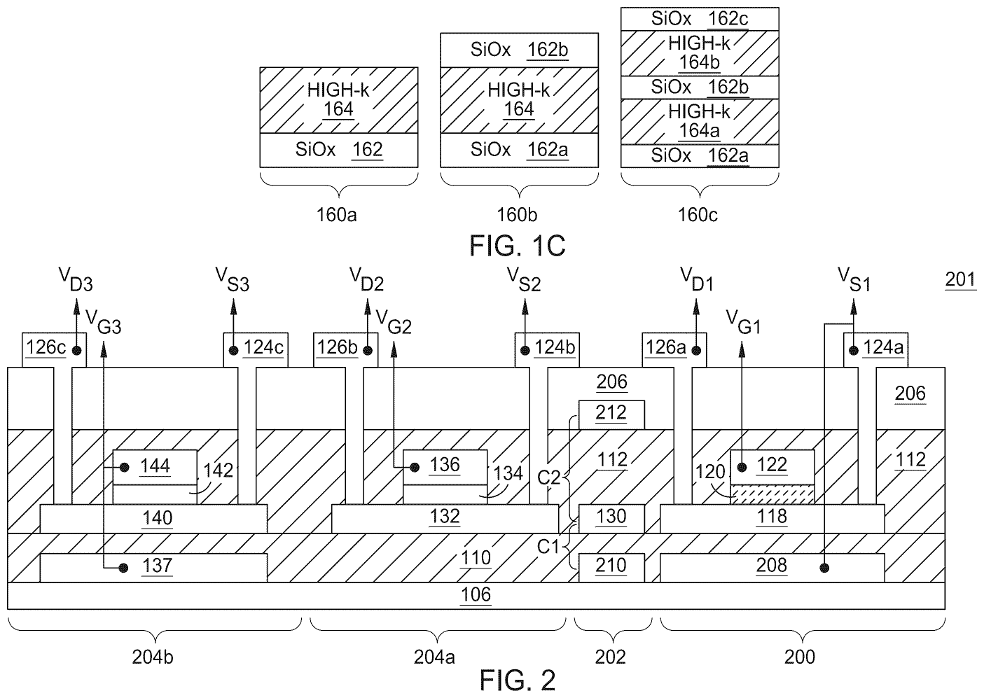

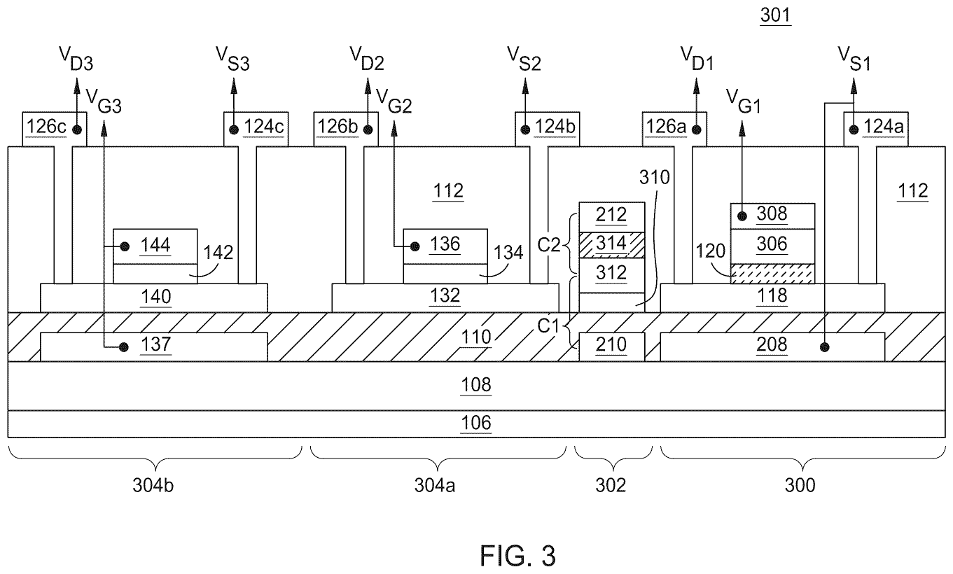

FIGS. 2-3 are schematic cross-sectional views of other exemplary devices 201 and 301 including the first bottom GI layer 110 and the first ILD layer 112 having a dielectric constant greater than five, according to embodiments.

As shown in FIG. 2, the exemplary device 201 includes a driving TFT structure 200, a capacitor structure 202, and a switching TFT structure, which may optionally be a first switching TFT structure 204a or a second switching TFT structure 204b.

The driving TFT structure 200 is similar to the driving TFT structure 100 shown in FIG. 1A, but the driving TFT structure 200 includes a first bottom gate 208 disposed on the first buffer layer 106 (that is not shared with the capacitor 202), the first bottom GI layer 110 disposed over the first bottom gate 208, and a second ILD layer 206 disposed on the first ILD layer 112. The first ILD layer 112 has a thickness that is less than about 300 nm, and the second ILD layer 206 has a thickness that is less than about 600 nm. The second source electrode 124b and the second drain electrode 126b are formed through the second ILD layer 206 and the first ILD layer 112. The first source electrode 124a and the first bottom gate 208 are associated with the source voltage V_{S1}. Further, the first bottom GI layer 110 and the first ILD layer 112 have a dielectric constant greater than five. Accordingly, the first bottom GI layer 110 and/or the first ILD layer 112 are comprised of one or more of SiNx, SiOx, SiON, AlOx, HfOx, ZrOx, and TiOx. The first top GI layer 120 has a dielectric constant that is less than five.

The capacitor structure 202 is coupled to the driving TFT structure 200 and includes a first capacitor C1 and/or a second capacitor C2. The first capacitor C1 includes a first bottom gate 210, a portion of the first bottom GI layer 110 disposed over the first bottom gate 210, and a portion of the metal oxide layer 130 disposed on the first bottom GI layer 110. The second capacitor C2 includes an additional portion of the metal oxide layer 130, a portion of the first ILD layer 112 disposed on the metal oxide layer 130, and a second top gate 212 disposed on the portion of the first ILD layer 112.

The device 201 further includes a switching TFT structure such as, for example, the first switching TFT structure 204a or the second switching TFT structure 204b. The first switching TFT structure 204a is similar to the first switching TFT structure 104a shown in FIG. 1A, but the second source electrode 124b and the second drain electrode 126b are formed through the second ILD layer 206 and the first ILD layer 112. The second switching TFT structure 204b is similar to the second switching TFT structure 104b shown in FIG. 1A, but the second drain electrode 126b are formed through the second ILD layer 206 and the first ILD layer 112.

As shown in FIG. 3, the exemplary device 301 includes a driving TFT structure 300, a capacitor structure 302, and a switching TFT structure, which may optionally be a first switching TFT structure 304a or a second switching TFT structure 304b.

The driving TFT structure 300 is similar to the driving TFT structure 100 shown in FIG. 1A, but the driving TFT structure 300 includes a first bottom gate 208 disposed on the second buffer layer 108, the first bottom GI layer 110 disposed on the first bottom gate 208, a second top GI layer 306 disposed on the first top GI layer 120, a second top gate 308 disposed on the second top GI layer 306, and the first ILD layer 112 disposed on the second top gate 308 and portions of the metal oxide layer 118 and the first bottom GI layer 110. The second top GI layer 306 has a thickness that is less than about 300 nm, and the first ILD layer 112 has a thickness that is about 600 nm. The second top gate 308 of the driving TFT structure 300 is associated with the gate voltage V_{G3}. The first source electrode 124a and the first bottom gate 208 are associated with the source voltage V_{S1}. Further, the first bottom GI layer 110 has a dielectric constant greater than five. Accordingly, the first bottom GI layer 110 is comprised of one or more of SiNx, SiOx, SiON, AlOx, HfOx, ZrOx, and TiOx. The first top GI layer 120 has a dielectric constant that is greater than or less than five. When the first top GI layer 120 has a dielectric constant that is greater than five, the first top GI layer 120 is also comprised of one or more of SiOx, AlOx, HfOx, ZrOx, and TiOx.

The capacitor structure 302 is coupled to the driving TFT structure 300 and includes a first capacitor C1 and/or a second capacitor C2. The first capacitor C1 includes a first bottom gate 210 disposed on the second buffer layer 108, a portion of the first bottom GI layer 110 disposed over the first bottom gate 210, a first top GI layer 310 disposed on the portion of the first bottom GI layer 110, and a portion of a first top gate 312 disposed on the first top GI layer 310. The second capacitor C2 includes an additional portion of the first top gate 312, a second top GI layer 314 disposed on the additional portion of the first top gate 312, and a second top gate 212 disposed on the second top GI layer 314. The second top GI layer 314 of the second capacitor C2 has a dielectric constant that is greater than or less than five.

The device 301 further includes a switching TFT structure such as, for example, the first switching TFT structure 304a or the second switching TFT structure 304b. The first switching TFT structure 304a is similar to the first switching TFT structure 104a shown in FIG. 1A. The second switching TFT structure 304b is similar to the second switching TFT structure 104b shown in FIG. 1A, but the first bottom gate 137 is disposed on the second buffer layer 108.

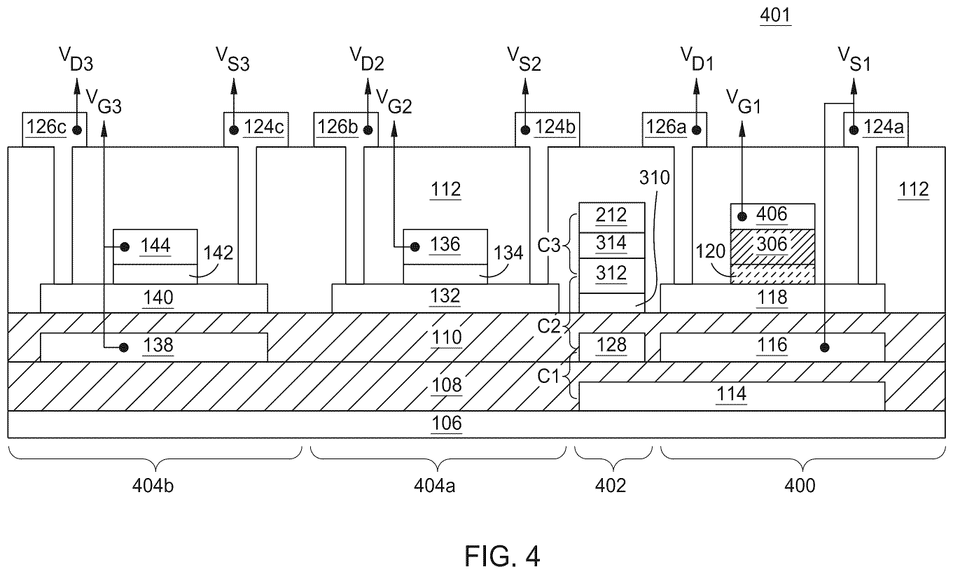

FIG. 4 is a schematic cross-sectional view of another exemplary device 401 including the second buffer layer 108, the first bottom GI layer 110, and the second top GI layer 306 having a dielectric constant greater than five, according to embodiments. The exemplary device 401 includes a driving TFT structure 400, a capacitor structure 402, and a switching TFT structure, which may optionally be a first switching TFT structure 404a or a second switching TFT structure 404b.

The driving TFT structure 400 is similar to the driving TFT structure 100 shown in FIG. 1A, but the driving TFT structure 400 includes the second top GI layer 306 disposed on the first top GI layer 120 and the second top gate 406 disposed on the second top GI layer 306. The second top gate 406 of the driving TFT structure 400 is associated with the gate voltage V_{G3}. The first source electrode 124a and the second bottom gate 116 are associated with the source voltage V_{S1}. Further, the second buffer layer 108, the first bottom GI layer 110, and the second top GI layer 306 have a dielectric constant greater than five. Accordingly, the second buffer layer 108, the first bottom GI layer 110, and/or the second top GI layer 306 are comprised of one or more of SiNx, SiOx, SiON, AlOx, HfOx, ZrOx, and TiOx. The first top GI layer 120 has a dielectric constant that is greater than or less than five. When the first top GI layer 120 has a dielectric constant that is greater than five, the first top GI layer 120 is comprised of one or more of SiOx, AlOx, HfOx, ZrOx, and TiOx.

The capacitor structure 402 is coupled to the driving TFT structure 400 and includes a first capacitor C1, a second capacitor C2, and/or a third capacitor C3. The first capacitor C1 includes the first bottom gate 114 disposed on the first buffer layer 106, a portion of the second buffer layer 108 disposed on the first bottom gate 114, and a portion of the second bottom gate 128 disposed on the portion of the second buffer layer 108. The second capacitor C2 includes an additional portion of the second bottom gate 128, the first top GI layer 310 disposed on the portion of the second buffer layer 110, and a portion of the first top gate 312 disposed on the first top GI layer 310. The third capacitor C3 includes an additional portion of the first top gate 312, the second top GI layer 314 disposed on the additional portion of the first top gate 312, and the second top gate 212 disposed on the second top GI layer 314.

The device 401 further includes a switching TFT structure such as, for example, the first switching TFT structure 404a or the second switching TFT structure 404b. The first switching TFT structure 404a is similar to the first switching TFT structure 104a shown in FIG. 1A. The second switching TFT structure 404b is similar to the second switching TFT structure 104b shown in FIG. 1A, but the second bottom gate 138 is disposed on the second buffer layer 108. The second bottom gate 138 and the first top gate 144 are associated with the gate voltage V_{G3}.

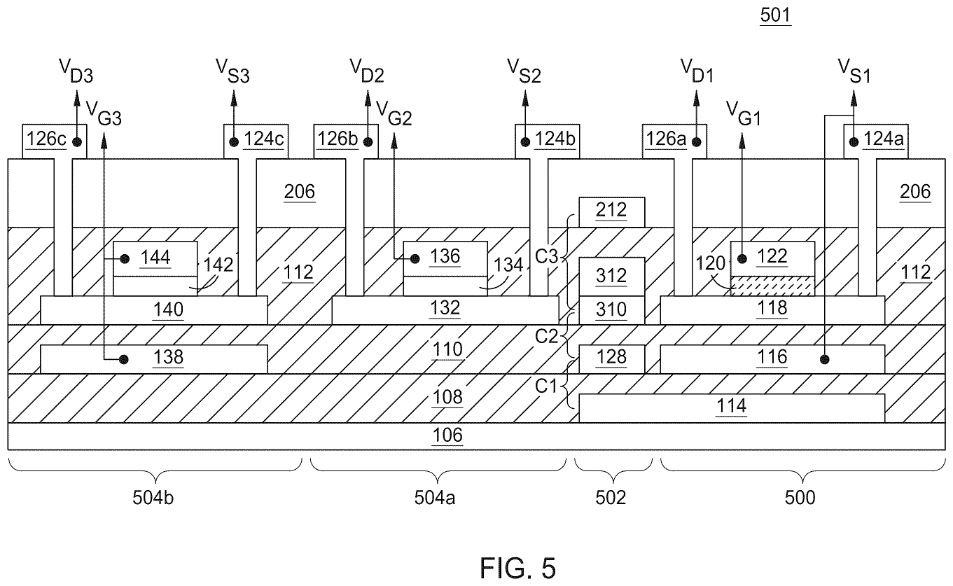

FIG. 5 is a schematic cross-sectional view of another exemplary device 501 including the second buffer layer 108, the first bottom GI layer 110, and the first ILD layer 112 having a dielectric constant greater than five, according to embodiments. The exemplary device 501 includes a driving TFT structure 500, a capacitor structure 502, and a switching TFT structure, which may optionally be a first switching TFT structure 504a or a second switching TFT structure 504b.

The driving TFT structure 500 is similar to the driving TFT structure 100 shown in FIG. 1A, but the driving TFT structure 500 includes the second ILD layer 206 disposed on the first ILD layer 112. Thus, the second source electrode 124b and the second drain electrode 126b are formed through the second ILD layer 206 and the first ILD layer 112. Further, the second buffer layer 108, the first bottom GI layer 110, and the first ILD layer 112 have a dielectric constant greater than five. Accordingly, the second buffer layer 108, the first bottom GI layer 110, and/or the first ILD layer 112 are comprised of one or more of SiNx, SiOx, SiON, AlOx, HfOx, ZrOx, and TiOx. The first top GI layer 120 has a dielectric constant that is less than five.

The capacitor structure 502 is similar to the capacitor structure 402 shown in FIG. 4, but the third capacitor C3 includes a portion of the first ILD layer 112 disposed on the first top gate 312 and a second top gate 212 disposed on the portion of the first ILD layer 112.

The device 501 further includes a switching TFT structure such as, for example, the first switching TFT structure 504a or the second switching TFT structure 504b. The first switching TFT structure 504a is similar to the first switching TFT structure 204a shown in FIG. 2. The second switching TFT structure 504b is similar to the second switching TFT structure 204b shown in FIG. 2, but a second bottom gate 138 is disposed on the second buffer layer 108.

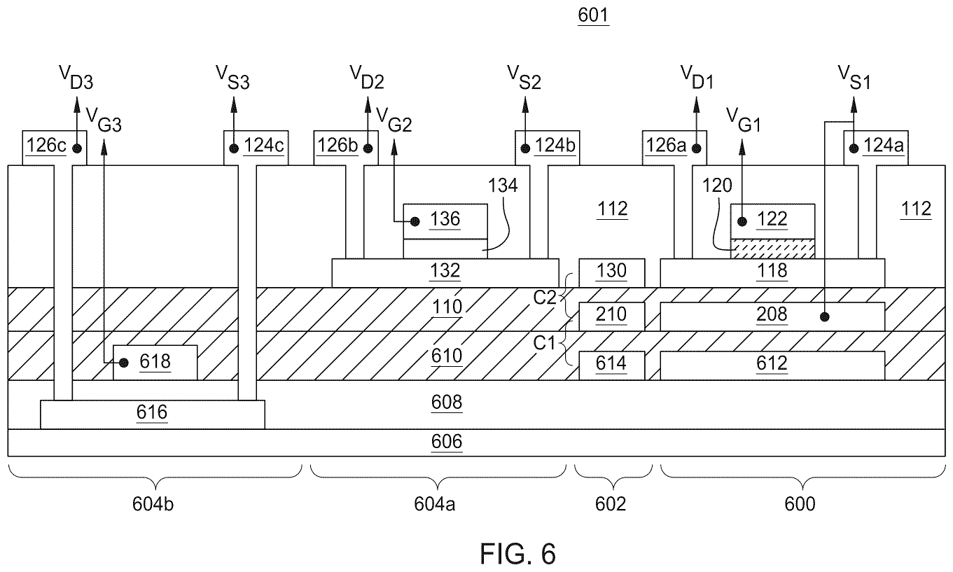

FIGS. 6-8 are schematic cross-sectional views of other exemplary devices including a first low temperature polycrystalline silicon (LTPS) ILD layer 610 and the first bottom GI layer 110 having a dielectric constant greater than five, according to embodiments.

As shown in FIG. 6, the exemplary device 601 includes a driving TFT structure 600, a capacitor structure 602, and a switching TFT structure, which may optionally be a first switching TFT structure 604a or a second switching TFT structure 604b.

The driving TFT structure 600 is similar to the driving TFT structure 200 shown in FIG. 2, but the driving TFT structure 600 includes the first LTPS buffer layer 606, a first LTPS top GI layer 608 disposed on the first LTPS buffer layer, a first LTPS top gate 612 disposed on the first LTPS top GI layer 612, a first LTPS ILD layer 610 disposed on the first LTPS top gate 612, and the first bottom gate 208 disposed on the first LTPS ILD layer 610. The first LTPS top GI layer 608 has a thickness that is less than about 200 nm and the first LTPS ILD layer 610 has a thickness that is less than about 300 nm. The first bottom gate 208 and the first source electrode 124a are associated with the source voltage V_{S1}. Further, the first LTPS ILD layer 610 and the first bottom GI layer 110 have a dielectric constant greater than five. Accordingly, the first LTPS ILD layer 610 and/or the first bottom GI layer 110 are comprised of one or more of SiNx, SiOx, SiON, AlOx, HfOx, ZrOx, and TiOx. The first top GI layer 120 has a dielectric constant that is less than five.

The capacitor structure 602 is similar to the capacitor structure 102 shown in FIG. 1A, but the first capacitor C1 includes a first LTPS top gate 614 disposed on the first LTPS top GI layer 608, a portion of the first LTPS ILD layer 610 disposed on the first LTPS top gate 614, and a portion of a first bottom gate 210 disposed on the portion of the first LTPS ILD layer 610. Further, the second capacitor C2 includes an additional portion of the first bottom gate 210, a portion of the first bottom GI layer 110 disposed on the additional portion of the first bottom gate 210, and the metal oxide layer 130 disposed on the portion of the first bottom GI layer 110.

The device 601 further includes a switching TFT structure such as, for example, the first switching TFT structure 604a or the second switching TFT structure 504b. The first switching TFT structure 604a is similar to the first switching TFT structure 104a shown in FIG. 1A. The second switching TFT structure 604b includes a polysilicon (p-Si) layer 616 disposed on the first LTPS buffer layer 606 and a first LTPS top gate 618 disposed on the first LTPS top GI layer 608. The first LTPS top gate 618 is associated with the gate voltage V_{G3}. Further, the third source electrode 124c and the third drain electrode 126c are in contact with the p-Si layer 616 and are formed through the first LTPS top GI layer 608, the first LTPS ILD layer 610, the first bottom GI layer 110, and the first ILD layer 112.

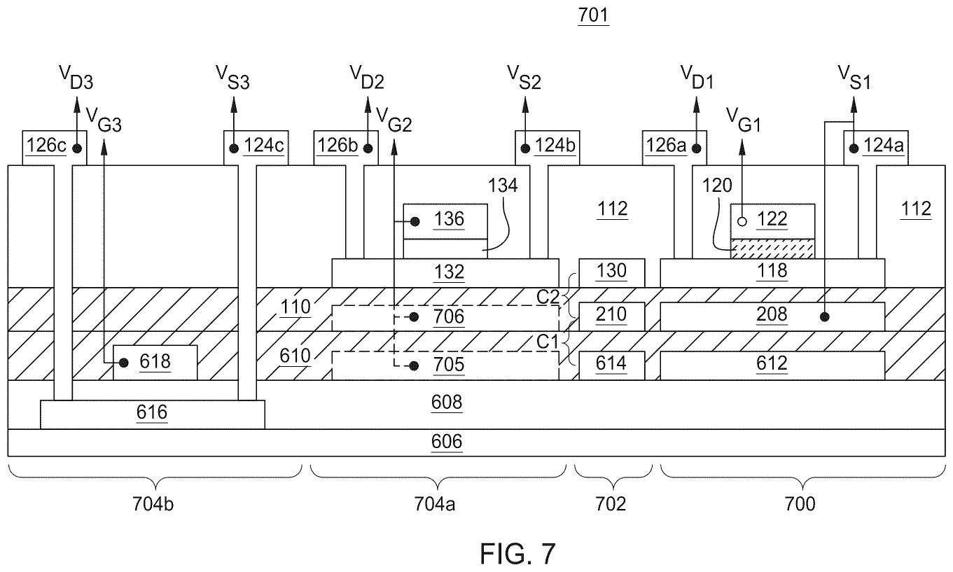

As shown in FIG. 7, the exemplary device 701 includes a driving TFT structure 700, a capacitor structure 702, and a switching TFT structure, which may optionally be a first switching TFT structure 704a or a second switching TFT structure 704b.

The driving TFT structure 700 is similar to the driving TFT structure 600 shown in FIG. 6, but the first top GI layer 120 has a dielectric constant greater than or less than five. When the first top GI layer 120 has a dielectric constant greater than or less than five, the first top GI layer 120 is comprised of one or more of SiOx, AlOx, HfOx, ZrOx, and TiOx. The first top GI layer 120 has a dielectric constant that is less than five.

The capacitor structure 702 and the second switching TFT structure 704b are also respectively similar to the capacitor structure 702 and the second switching TFT structure 604b shown in FIG. 6. While the first switching TFT structure 704a is also similar to the first switching TFT structure 604a shown in FIG. 6, the first switching TFT structure 704a further includes a first LTPS top gate 705 disposed on the first LTPS top GI layer 608, or a first bottom gate 706 disposed on the first LTPS ILD layer 610. The first LTPS top bottom gate 705 and the first bottom gate 706 may be collectively referred to herein as the bottom gate 705 or 706. The first top gate 136 and the bottom gate 705 or 706 are associated with the gate voltage V_{G2}.

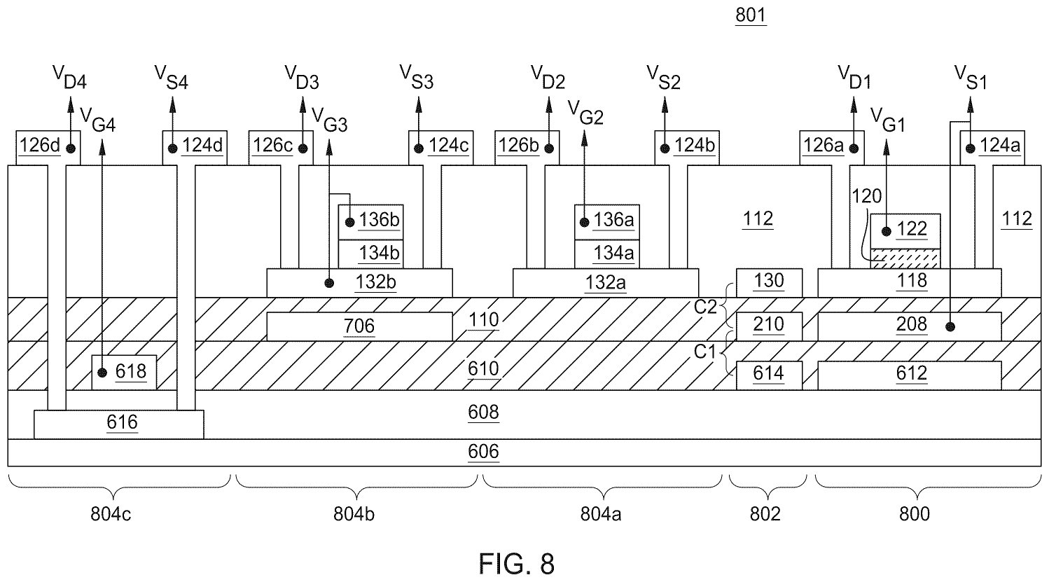

As shown in FIG. 8, the exemplary device 801 includes a driving TFT structure 800, a capacitor structure 802, and a switching TFT structure, which may optionally be a first switching TFT structure 804a, a second switching TFT structure 804b, or a third switching TFT structure 804c.

The driving TFT structure 800 and the capacitor structure 802 are respectively similar to the driving TFT structure 600 and the capacitor structure 602 shown in FIG. 6.

The first switching TFT structure 804a is similar to the first switching TFT structure 604a shown in FIG. 6, and includes a metal oxide layer 132a disposed on the first bottom GI layer 110, a first top GI layer 134a disposed on a portion of the metal oxide layer 132a, and a first top gate 136a disposed on the first top GI layer 134a, and the first ILD layer 112 disposed on the first top gate 136a and portions of the metal oxide layer 132a and the first bottom GI layer 110. In the first switching TFT structure 804a, the first top gate 136a is associated with the gate voltage V_{G2}.

The second switching TFT structure 804b is similar to the first switching TFT structure 704a shown in FIG. 7, and includes a metal oxide layer 132b disposed on the first bottom GI layer 110, a first top GI layer 134b disposed on a portion of the metal oxide layer 132b, and a first top gate 136b disposed on the first top GI layer 134b, and the first ILD layer 112 disposed on the first top gate 136b and portions of the metal oxide layer 132b and the first bottom GI layer 110. The second switching TFT structure 804b also includes the first bottom gate 706 disposed on the first LTPS ILD layer 610. In the second switching TFT structure 804b, the first bottom gate 706 and the first top gate 136b are associated with the gate voltage V_{G3}. The third source electrode 124c and the third drain electrode 126c are associated with a source voltage V_{S3} and a drain voltage V_{D3}, respectively.

The third switching TFT structure 804c is similar to the second switching TFT structure 704b shown in FIG. 7, but the third switching TFT structure 804c includes a fourth source electrode 124d and a fourth drain electrode 126d (similar to the third source electrode 124c and the third drain electrode 126c of the second switching TFT structure 704b). In the third switching TFT structure 804c, the first LTPS top gate 618 is associated with the gate voltage V_{G4}, and the third source electrode 124c and the third drain electrode 126c are associated with a source voltage V_{S4} and a drain voltage V_{D4}, respectively.

In various embodiments of the present disclosure, layers or other materials are referred to as being etched. It is understood that the etching of these materials can be performed using any conventional methods used in semiconductor manufacturing, such as, but not limited to, reactive ion etching (RIE), dry etching, wet etching, plasma etching, microloading, the selective etching of any of the above, combinations of the above, and any other suitable method. It is to be understood that when a method operation is described herein as etching two or more types of materials, or two or more portions of the same material, the etching can occur simultaneously with the same etching process, or the etching can be performed in separate suboperations using different etching processes. For example, an operation describing etching a metal and a dielectric includes a first etching suboperation using a first etching process that etches the metal, and the operation further includes a second etching suboperation using a second etching process that etches the dielectric.

The previous description is provided to enable any person skilled in the art to practice the various aspects described herein. Various modifications to these aspects will be readily apparent to those skilled in the art, and the generic principles defined herein may be applied to other aspects. Thus, the claims are not intended to be limited to the aspects shown herein, but is to be accorded the full scope consistent with the language of the claims, wherein reference to an element in the singular is not intended to mean “one and only one” unless specifically so stated, but rather “one or more.” Unless specifically stated otherwise, the term “some” refers to one or more. All structural and functional equivalents to the elements of the various aspects described throughout this disclosure that are known or later come to be known to those of ordinary skill in the art are expressly incorporated herein by reference and are intended to be encompassed by the claims. Moreover, nothing disclosed herein is intended to be dedicated to the public regardless of whether such disclosure is explicitly recited in the claims. No claim element is to be construed under the provisions of 35 U.S.C. § 112 (f) unless the element is expressly recited using the phrase “means for” or, in the case of a method claim, the element is recited using the phrase “step for.”

While various examples of the invention have been described above, it should be understood that they have been presented by way of example only, and not by way of limitation. Likewise, the various diagrams may depict an example architectural or other configuration for the disclosure, which is done to aid in understanding the features and functionality that can be included in the disclosure. The disclosure is not restricted to the illustrated example architectures or configurations, but can be implemented using a variety of alternative architectures and configurations. Additionally, although the disclosure is described above in terms of various example examples and aspects, it should be understood that the various features and functionality described in one or more of the individual examples are not limited in their applicability to the particular example with which they are described. They instead can be applied, alone or in some combination, to one or more of the other examples of the disclosure, whether or not such examples are described, and whether or not such features are presented as being a part of a described example. Thus the breadth and scope of the present disclosure should not be limited by any of the above-described example examples.

All references cited herein are incorporated herein by reference in their entirety. To the extent publications and patents or patent applications incorporated by reference contradict the disclosure contained in the specification, the specification is intended to supersede and/or take precedence over any such contradictory material.

Unless otherwise defined, all terms (including technical and scientific terms) are to be given their ordinary and customary meaning to a person of ordinary skill in the art, and are not to be limited to a special or customized meaning unless expressly so defined herein.

Terms and phrases used in this application, and variations thereof, especially in the appended claims, unless otherwise expressly stated, should be construed as open ended as opposed to limiting. As examples of the foregoing, the term ‘including’ should be read to mean ‘including, without limitation,’ ‘including but not limited to,’ or the like; the term ‘including’ as used herein is synonymous with ‘including,’ ‘containing,’ or ‘characterized by,’ and is inclusive or open-ended and does not exclude additional, unrecited elements or method steps; the term ‘having’ should be interpreted as ‘having at least;’ the term ‘includes’ should be interpreted as ‘includes but is not limited to;’ the term ‘example’ is used to provide example instances of the item in discussion, not an exhaustive or limiting list thereof; adjectives such as ‘known’, ‘normal’, ‘standard’, and terms of similar meaning should not be construed as limiting the item described to a given time period or to an item available as of a given time, but instead should be read to encompass known, normal, or standard technologies that may be available or known now or at any time in the future; and use of terms like ‘preferably,’ ‘preferred,’ ‘desired,’ or ‘desirable,’ and words of similar meaning should not be understood as implying that certain features are critical, essential, or even important to the structure or function of the invention, but instead as merely intended to highlight alternative or additional features that may or may not be utilized in a particular example of the invention. Likewise, a group of items linked with the conjunction ‘and’ should not be read as requiring that each and every one of those items be present in the grouping, but rather should be read as ‘and/or’ unless expressly stated otherwise. Similarly, a group of items linked with the conjunction ‘or’ should not be read as requiring mutual exclusivity among that group, but rather should be read as ‘and/or’ unless expressly stated otherwise.

The term “including as used herein is synonymous with “including,” “containing,” or “characterized by” and is inclusive or open-ended and does not exclude additional, unrecited elements or method steps.

All numbers expressing quantities of ingredients, reaction conditions, and so forth used in the specification are to be understood as being modified in all instances by the term ‘about.’ Accordingly, unless indicated to the contrary, the numerical parameters set forth herein are approximations that may vary depending upon the desired properties sought to be obtained. At the very least, and not as an attempt to limit the application of the doctrine of equivalents to the scope of any claims in any application claiming priority to the present application, each numerical parameter should be construed in light of the number of significant digits and ordinary rounding approaches.

Furthermore, although the foregoing has been described in some detail by way of illustrations and examples for purposes of clarity and understanding, it is apparent to those skilled in the art that certain changes and modifications may be practiced. Therefore, the description and examples should not be construed as limiting the scope of the invention to the specific examples and examples described herein, but rather to also cover all modification and alternatives coming with the true scope and spirit of the invention.

### Example Embodiments

Embodiment 1: A thin-film transistor (TFT) structure, comprising: a first buffer layer; a second buffer layer disposed on the first buffer layer; a first bottom gate disposed on the second buffer layer; a first bottom gate insulator (GI) layer disposed on the first bottom gate; a metal oxide layer disposed on the first bottom GI layer; a first top GI layer disposed on the metal oxide layer; a second top GI layer disposed on the first top GI layer; a second top gate disposed on the second top GI layer; and a first interlayer dielectric (ILD) layer disposed on the first top gate and the metal oxide layer; wherein the first bottom GI layer has a dielectric constant greater than five.

Embodiment 2: The TFT structure of Embodiment 1, wherein the first top GI layer has a dielectric constant that is less than five.

Embodiment 3: The TFT structure of Embodiment 1, wherein the first top GI layer has a dielectric constant that is greater than five.

Embodiment 4: The TFT structure of Embodiment 3, wherein the first top GI layer is comprised of one or more of silicon oxide (SiOx), aluminum oxide (AlOx), hafnium oxide (HfOx), zirconium oxide (ZrOx), and titanium oxide (TiOx) resulting in a dielectric constant of greater than five.

Embodiment 5: The TFT structure of Embodiment 1, wherein the driving TFT structure is coupled to a capacitor structure comprising: a first capacitor comprising: a first bottom gate disposed on the second buffer layer; a portion of the first bottom GI layer disposed on the first bottom gate; a first top GI layer disposed on the portion of the first bottom GI layer; and a portion of a first top gate disposed on the first top GI layer; and a second capacitor comprising: an additional portion of the first top gate; a second top GI layer disposed on the additional portion of the first top gate of the first capacitor, wherein the second top GI layer has a dielectric constant greater than five; and a second top gate disposed on the second top GI layer.

Embodiment 6: The TFT structure of Embodiment 1, wherein the driving TFT structure is coupled to a switching TFT structure comprising: a metal oxide layer disposed on the first bottom GI layer; a first top GI layer disposed on the metal oxide layer; a first top gate disposed on the first top GI layer; and the first ILD layer disposed on the first top gate and the metal oxide layer.

Embodiment 7: The TFT structure of Embodiment 1, wherein the driving TFT structure is coupled to a switching TFT comprising: a first bottom gate disposed on the second buffer layer; a metal oxide layer disposed on the first bottom GI layer; a first top GI layer disposed on the metal oxide layer; a first top gate disposed on the first top GI layer; and the first ILD layer disposed on the first top gate and the metal oxide layer.

I claim:

1. A thin-film transistor (TFT) structure, comprising:
a first buffer layer;
a first bottom gate disposed on the first buffer layer;
a second buffer layer disposed on the first bottom gate;
a second bottom gate disposed on the second buffer layer;
a first bottom gate insulator (GI) layer disposed on the second bottom gate;
a metal oxide layer disposed on the first bottom GI layer;
a first top GI layer disposed on the metal oxide layer;
a first top gate disposed on the first top GI layer; and
a first interlayer dielectric (ILD) layer disposed on the first top gate and the metal oxide layer,
wherein the second buffer layer and the first bottom GI layer have a dielectric constant greater than five.

2. The TFT structure of claim 1, wherein the second buffer layer and the first bottom GI layer are each comprised of one or more of silicon nitride (SiNx), silicon oxide (SiOx), silicon oxynitride (SiON), aluminum oxide (AlOx), hafnium oxide (HfOx), zirconium oxide (ZrOx), or titanium oxide (TiOx).

3. The TFT structure of claim 1, wherein the first top GI layer has a dielectric constant that is less than five.

4. The TFT structure of claim 1, wherein the first top GI layer has a dielectric constant that is greater than five.

5. The TFT structure of claim 4, wherein the first top GI layer is comprised of one or more of silicon oxide (SiOx), aluminum oxide (AlOx), hafnium oxide (HfOx), zirconium oxide (ZrOx), and titanium oxide (TiOx).

6. The TFT structure of claim 1, wherein the TFT structure is coupled to a capacitor structure comprising:
a first capacitor comprising:
a portion of the first bottom gate disposed on the first buffer layer; and
a portion of a second bottom gate of the capacitor structure disposed on the second buffer layer; and
a second capacitor comprising:
an additional portion of the second bottom gate of the capacitor structure disposed on the second buffer layer; and
a metal oxide layer of the capacitor structure disposed on the first bottom GI layer.

7. The TFT structure of claim 1, wherein the TFT structure is coupled to an additional TFT structure comprising:
a metal oxide layer of the additional TFT structure disposed on the first bottom GI layer;
a first top GI layer of the additional TFT structure disposed on the metal oxide layer of the additional TFT structure;
a first top gate of the additional TFT structure disposed on the first top GI layer of the additional TFT structure; and
the first ILD layer disposed on the first top gate of the additional TFT structure and the metal oxide layer of the additional TFT structure.

8. The TFT structure of claim 1, wherein the TFT structure is coupled to an additional TFT structure comprising:
a bottom gate of the additional TFT structure disposed on the first buffer layer or the second buffer layer;
a metal oxide layer of the additional TFT structure disposed on the first bottom GI layer;
a first top GI layer of the additional TFT structure disposed on the metal oxide layer of the additional TFT structure;
a first top gate of the additional TFT structure disposed on the first top GI layer of the additional TFT structure; and
the first ILD layer disposed on the first top gate of the additional TFT structure and the metal oxide layer of the additional TFT structure.

9. A thin-film transistor (TFT) structure, comprising:
a first low temperature polycrystalline silicon (LTPS) buffer layer;
a first LTPS top gate insulator (GI) layer disposed on the first LTPS buffer layer;
a first LTPS top gate disposed on the first LTPS top GI layer;
a first LTPS interlayer dielectric (ILD) layer disposed on the first LTPS top gate;
a first bottom gate disposed on the first LTPS ILD layer;
a first bottom GI layer disposed on the first bottom gate;
a metal oxide layer disposed on the first bottom GI layer;
a first top GI layer disposed on the metal oxide layer;
a first top gate disposed on the first top GI layer; and
a first ILD layer disposed on the first top gate and the metal oxide layer,
wherein the first LTPS ILD layer and the first bottom GI layer have a dielectric constant that is greater than five.

10. The TFT structure of claim 9, wherein the first top GI layer has a dielectric constant that is less than five.

11. The TFT structure of claim 9, wherein the first top GI layer has a dielectric constant that is greater than five.

12. The TFT structure of claim 9, wherein the TFT structure is coupled to a capacitor structure comprising:
a first capacitor comprising:
a first LTPS top gate of the capacitor structure disposed on the first LTPS top GI layer; and
a portion of a first bottom gate of the capacitor structure disposed on the first LTPS ILD layer; and
a second capacitor comprising:
an additional portion of the first bottom gate of the capacitor structure disposed on the first LTPS ILD layer; and
a metal oxide layer of the capacitor structure disposed on the first bottom GI layer.

13. The TFT structure of claim 9, wherein the TFT structure is coupled to an additional TFT structure comprising:
a metal oxide layer of the additional TFT structure disposed on the first bottom GI layer;
a first top GI layer of the additional TFT structure disposed on the metal oxide layer of the additional TFT structure;
a first top gate of the additional TFT structure disposed on the first top GI layer of the additional TFT structure; and
the first ILD layer disposed on the first top gate of the additional TFT structure and the metal oxide layer of the additional TFT structure.

14. The TFT structure of claim 9, wherein the TFT structure is coupled to an additional TFT structure comprising:
a polysilicon (p-Si) layer disposed on the first LTPS buffer layer; and
a first LTPS top gate of the additional TFT structure disposed on the first LTPS top GI layer.

15. The TFT structure of claim 9, wherein the TFT structure is coupled to an additional TFT structure comprising:
a first bottom gate of the additional TFT structure disposed on the first LTPS ILD layer;
a metal oxide layer of the additional TFT structure disposed on the first bottom GI layer of the additional TFT structure;
a first top GI layer of the additional TFT structure disposed on the metal oxide layer of the additional TFT structure;
a first top gate of the additional TFT structure disposed on the first top GI layer of the additional TFT structure; and
the first ILD layer disposed on the first top gate of the additional TFT structure and the metal oxide layer of the additional TFT structure.

16. The TFT structure of claim 9, wherein the TFT structure is coupled to an additional TFT structure comprising:
a first LTPS top gate of the additional TFT structure disposed on the first LTPS top GI layer;
a metal oxide layer of the additional TFT structure disposed on the first bottom GI layer;
a first top GI layer of the additional TFT structure disposed on the metal oxide layer of the additional TFT structure;
a first top gate of the additional TFT structure disposed on the first top GI layer of the additional TFT structure; and
the first ILD layer disposed on the first top gate of the additional TFT structure and the metal oxide layer of the additional TFT structure.

17. A thin-film transistor (TFT) structure, comprising:
a first buffer layer;
a first bottom gate disposed on the first buffer layer;
a first bottom gate insulator (GI) layer disposed on the first bottom gate;
a metal oxide layer disposed on the first bottom GI layer;
a first top GI layer disposed on the metal oxide layer; and
a first interlayer dielectric (ILD) layer disposed on the metal oxide layer,
wherein the first bottom GI layer and the first ILD layer have a dielectric constant greater than five.

18. The TFT structure of claim 17, wherein a second ILD layer is disposed on the first ILD layer.

19. The TFT structure of claim 17, wherein the first top GI layer has a dielectric constant less than five.

20. The TFT structure of claim 17, wherein the first top GI layer has a dielectric constant greater than five.
